(19) United States
(12) Patent Application Publication
(10) Pub. No.: US 2026/0173389 A1
(43) Pub. Date: Jun. 18, 2026

(54) SEMICONDUCTOR DEVICE INCLUDING TRANSISTOR

(71) Applicant: SK hynix Inc., Icheon-si (KR)

(72) Inventors: Sang Hyun SUNG, Icheon-si (KR); Dong Hyuk KIM, Icheon-si (KR); Tae Sung PARK, Icheon-si (KR); Soo Nam JUNG, Icheon-si (KR)

(21) Appl. No.: 19/184,549

(22) Filed: Apr. 21, 2025

(30) Foreign Application Priority Data
Dec. 18, 2024 (KR) 10-2024-0189368

(51) Int. Cl. H10B 43/40; H10B 41/10; H10B 41/41; H10B 43/10

(52) U.S. Cl. CPC H10B 43/40; H10B 41/10; H10B 41/41; H10B 43/10

(57) ABSTRACT

A semiconductor device includes a first transistor; and a second transistor sharing an active area with the first transistor. The active area includes a common active area between a channel area of the first transistor and a channel area of the second transistor. The common active area includes a first section extending in a second horizontal direction perpendicular to a first horizontal direction from the channel area of the first transistor; a second section extending in the second horizontal direction from the channel area of the second transistor; and a third section connected between the first and second sections, and extending in an oblique direction intersecting the first and second horizontal directions. At least a portion of the third section has a dimension in the first horizontal direction that is different from the dimension of each of the first section and the second section in the first horizontal direction.

### CROSS-REFERENCE TO RELATED APPLICATION

The present application claims priority under 35 U.S.C. § 119(a) to Korean Patent Application No. 10-2024-0189368 filed in the Korean Intellectual Property Office on Dec. 18, 2024, which is incorporated herein by reference in its entirety.

### BACKGROUND

### 1. Technical Field

Embodiments of the present disclosure relate to a semiconductor device including a transistor.

### 2. Related Art

A semiconductor device includes a memory device to which data is written. The memory device includes a memory cell array that includes memory cells and a peripheral circuit that controls the memory cell array.

### SUMMARY

In an embodiment, a semiconductor device may include: a first transistor; and a second transistor sharing an active area with the first transistor, wherein the active area includes a common active area between a channel area of the first transistor and a channel area of the second transistor, wherein the common active area from a plan view includes: a first section extending in a second horizontal direction perpendicular to a first horizontal direction from the channel area of the first transistor; a second section extending in the second horizontal direction from the channel area of the second transistor; and a third section connected between the first section and the second section, and extending in an oblique direction intersecting the first horizontal direction and the second horizontal direction, and wherein at least a portion of the third section has a dimension in the first horizontal direction that is different from the dimension of each of the first section and the second section in the first horizontal direction.

In an embodiment, a semiconductor device may include: a substrate defined with an active area; and first and second gate electrodes extending in a first horizontal direction on the substrate, and disposed parallel to each other; wherein the active area includes: a common active area disposed between the first gate electrode and the second gate electrode when viewed on a plan view; a first separate active area extending in a second horizontal direction perpendicular to the first horizontal direction from the common active area, and intersecting the first gate electrode; and a second separate active area extending in the second horizontal direction from the common active area, and intersecting the second gate electrode, wherein the common active area includes: a first section extending in the second horizontal direction from the first separate active area; a second section extending in the second horizontal direction from the second separate active area; and a third section connected between the first section and the second section, and extending in an oblique direction intersecting the first horizontal direction and the second horizontal direction, and wherein at least a portion of the third section has a dimension in the first horizontal direction that is different from the dimension of each of the first section and the second section in the first horizontal direction.

In an embodiment, a semiconductor device may include: a memory cell array; and a page buffer circuit connected to the memory cell array through bit lines, wherein the page buffer circuit includes first and second transistors that share one active area, wherein the active area includes a common active area between the channel area of the first transistor and the channel area of the second transistor, wherein the common active area from a plan view includes: a first section extending in a second horizontal direction perpendicular to a first horizontal direction from the channel area of the first transistor; a second section extending in the second horizontal direction from the channel area of the second transistor; and a third section connected between the first section and the second section, and extending in an oblique direction intersecting the first horizontal direction and the second horizontal direction, and wherein at least a portion of the third section has a dimension in the first horizontal direction that is smaller than the dimension of each of the first section and the second section in the first horizontal direction.

### BRIEF DESCRIPTION OF THE DRAWINGS

FIG. 1 is a block diagram of a semiconductor device according to an embodiment of the present disclosure.

FIG. 2 is an equivalent circuit diagram of a memory block illustrated in FIG. 1.

FIG. 3 is a plan view illustrating transistors of a semiconductor device according to an embodiment of the present disclosure.

FIG. 4 is a plan view illustrating an active area of FIG. 3.

FIG. 5 is a cross-sectional view taken along a line A-A′ of FIG. 3.

FIG. 6 and FIG. 7 are plan views illustrating transistors of semiconductor devices according to embodiments of the present disclosure.

FIG. 8 and FIG. 9 are plan views illustrating transistors for comparison with the present disclosure.

FIG. 10 is a cross-sectional view taken along a line B-B′ of FIG. 9.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element in between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

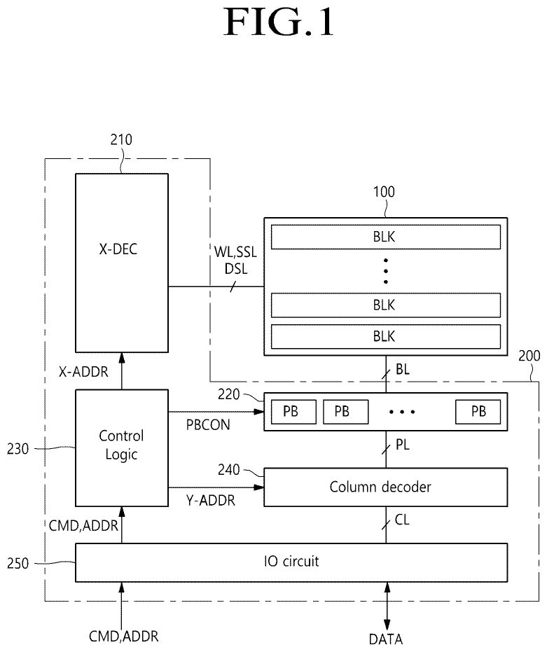

FIG. 1 is a block diagram of a semiconductor device according to an embodiment of the present disclosure.

Referring to FIG. 1, a semiconductor device according to an embodiment of the present disclosure may include a memory cell array 100 and a peripheral circuit 200. The peripheral circuit 200 may include a row decoder (X-DEC) 210, a page buffer circuit 220, a control logic 230, a column decoder 240 and an input/output circuit (IO circuit) 250.

The memory cell array 100 may include a plurality of memory cells. The memory cell array 100 may be configured as a three-dimensional memory array in which memory cells are stacked in a direction perpendicular to a substrate, but configurations are not limited thereto.

The memory cell array 100 may be connected to the row decoder 210 through word lines WL and select lines DSL and SSL. The select lines DSL and SSL may include a drain select line DSL and a source select line SSL. The memory cell array 100 may be connected to the page buffer circuit 220 through bit lines BL. The memory cell array 100 may store data received through the page buffer circuit 220 in a program operation, and may transmit stored data to the page buffer circuit 220 in a read operation.

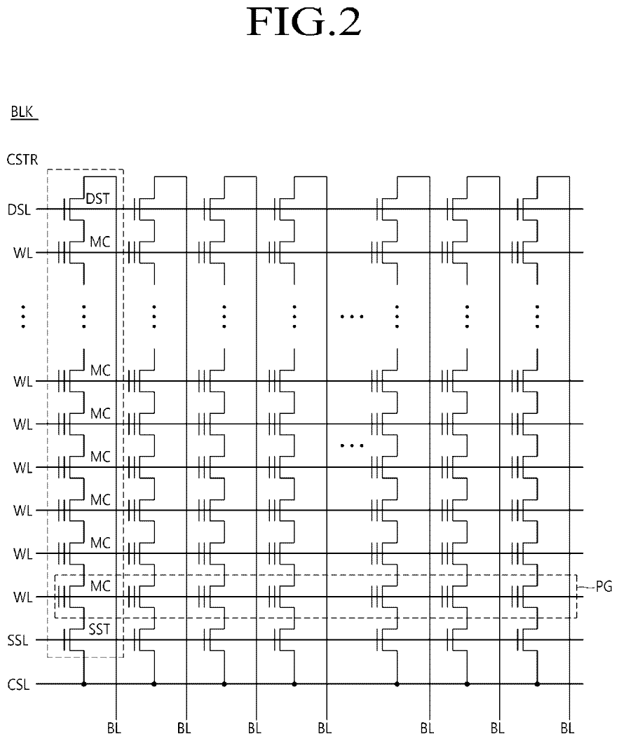

The memory cell array 100 may include a plurality of memory blocks BLK. Memory block BLK may be an erase unit. Word lines WL, select lines DSL and SSL and bit lines BL may be connected to each memory block BLK. Word lines WL and select lines DSL and SSL may be connected to a corresponding memory block BLK. Bit lines BL may be connected in common to a plurality of memory blocks BLK. An example of a memory block BLK will be described later with reference to FIG. 2.

The row decoder 210 may be connected to the memory cell array 100 through the word lines WL and the select lines DSL and SSL. The row decoder 210 may select one of the memory blocks BLK of the memory cell array 100 in response to a row address X-ADDR received from the control logic 230. The row decoder 210 may transmit operating voltages to word lines WL and select lines DSL and SSL connected to a selected memory block BLK.

The page buffer circuit 220 may be connected to the memory cell array 100 through the bit lines BL. The page buffer circuit 220 may include a plurality of page buffers PB that are connected to the bit lines BL, respectively. The page buffers PB may exchange data with the memory cell array 100 through the bit lines BL.

The page buffer circuit 220 may operate in response to a page buffer control signal PBCON that is received from the control logic 230. In a write operation, the page buffers PB may store data to be programmed to memory cells. The page buffers PB may apply voltages to the plurality of bit lines BL on the basis of the stored data. In a read operation or a verify read operation, the page buffers PB may sense voltages of the bit lines BL and store sensing results.

The control logic 230 may generate the page buffer control signal PBCON in response to a command CMD inputted through the input/output circuit 250. The control logic 230 may generate the row address X-ADDR and a column address Y-ADDR in response to an address signal ADDR inputted through the input/output circuit 250.

The column decoder 240 may be connected to the page buffers PB through page lines PL. The column decoder 240 exchanges data with the page buffers PB through the page lines PL in response to the column address Y-ADDR received from the control logic 230.

The input/output circuit 250 may exchange data with the column decoder 240 that is connected through column lines CL. The input/output circuit 250 may exchange data DATA with an external device, for example, a memory controller, through input/output paths, and may transmit the command CMD and the address signal ADDR received from the external device through the input/output paths, to the control logic 230. The input/output paths may include 2^{N} (where N is a natural number equal to or greater than 2) number of input/output pins. In an example, N=3, that is, eight input/output pins IO<0> to IO<7> may be included.

The entirety or a part of the peripheral circuit 200 may be disposed on a different plane from the memory cell array 100. For example, the memory cell array 100 may be disposed in a first semiconductor layer, and the peripheral circuit 200 may be disposed in a second semiconductor layer that vertically overlaps the first semiconductor layer. A part or the entirety of the peripheral circuit 200 disposed in the second semiconductor layer may vertically overlap the memory cell array 100.

FIG. 2 is an equivalent circuit diagram of a memory block illustrated in FIG. 1.

Referring to FIG. 2, each memory block BLK may include a plurality of cell strings CSTR that are connected between a plurality of bit lines BL and a common source line CSL.

Each cell string CSTR may be connected between a corresponding bit line BL and the common source line CSL. Each cell string CSTR may include a source select transistor SST that is connected to the common source line CSL, a drain select transistor DST that is connected to the bit line BL, and a plurality of memory cells MC that are connected between the source select transistor SST and the drain select transistor DST. The gate of the source select transistor SST may be connected to a source select line SSL. The gates of the memory cells MC may each be connected to a corresponding word line WL. The gate of the drain select transistor DST may be connected to a drain select line DSL.

The source select line SSL, the word lines WL and the drain select line DSL may be extended in a direction perpendicular to the bit line BL. The source select line SSL, the word lines WL and the drain select line DSL may be stacked in a direction perpendicular to the surface of a substrate to form a three-dimensional structure.

Memory cells MC included in the memory block BLK may be divided into physical page units or logical page units. For example, memory cells that share one word line WL and are connected to different cell strings CSTR may form one physical page PG. Pages may be the basic unit of a read operation.

For example, FIG. 2 illustrates that one drain select transistor DST and one source select transistor SST are provided in each cell string CSTR. However, two or more drain select transistors or two or more source select transistors may be provided in each cell string CSTR.

Hereinafter, in the accompanying drawings, two directions parallel to the top surface of a substrate will be defined as a first horizontal direction HD1 and a second horizontal direction HD2, respectively, and a direction that protrudes vertically from the top surface of the substrate will be defined as a vertical direction. The first horizontal direction HD1 and the second horizontal direction HD2 may perpendicularly intersect each other.

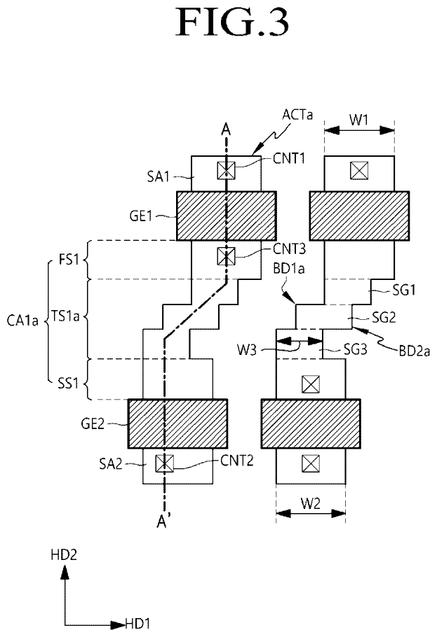

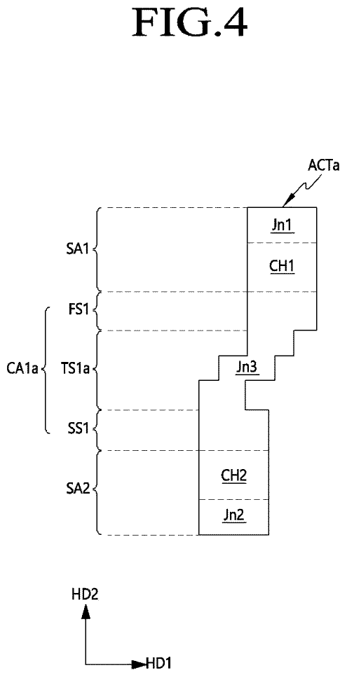

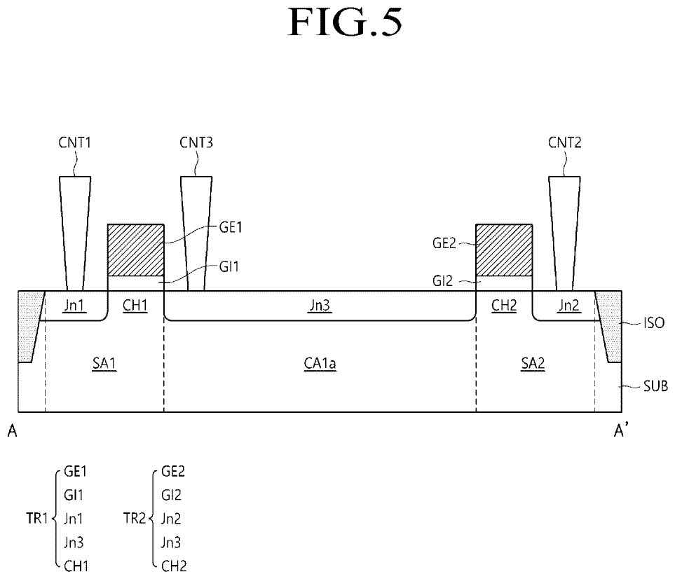

FIG. 3 is a plan view illustrating transistors of a semiconductor device according to an embodiment of the present disclosure, FIG. 4 is a plan view illustrating an active area of FIG. 3, and FIG. 5 is a cross-sectional view taken along a line A-A′ of FIG. 3.

Referring to FIG. 3 to FIG. 5, an isolation layer ISO may be formed on a substrate SUB to define an active area ACTa. The substrate SUB may be formed of a semiconductor material. For example, the substrate SUB may include silicon (Si), germanium (Ge) or silicon germanium (SiGe).

First and second transistors TR1 and TR2 may be disposed in the active area ACTa. The first and second transistors TR1 and TR2 may be included in the peripheral circuit 200 in the semiconductor device according to the embodiment of the present disclosure described above with reference to FIG. 1. For example, the first and second transistors TR1 and TR2 may be included in a page buffer circuit 220 described above with reference to FIG. 1.

The first transistor TR1 and the second transistor TR2 share one active area ACTa. The active area ACTa includes a first separate active area SA1, a second separate active area SA2 and a common active area CA1a. The first separate active area SA1 and the second separate active area SA2 are offset from each other in the first horizontal direction HD1. In other words, the first separate active area SA1 and the second separate active area SA2 are not aligned with each other in the second horizontal direction HD2.

A gate electrode (hereinafter referred to as a “first gate electrode”) GE1 of the first transistor TR1 and a gate electrode (hereinafter referred to as a “second gate electrode”) GE2 of the second transistor TR2 are disposed on the substrate SUB. The first gate electrode GE1 intersects the first separate active area SA1 in the first horizontal direction HD1, and the second gate electrode GE2 intersects the second separate active area SA2 in the first horizontal direction HD1.

The first separate active area SA1 includes a channel area (hereinafter referred to as a “first channel area”) CH1 of the first transistor TR1 that overlaps the first gate electrode GE1 in a vertical direction, and the second separate active area SA2 includes a channel area (hereinafter referred to as a “second channel area”) CH2 of the second transistor TR2 that overlaps the second gate electrode GE2 in the vertical direction. The first channel area CH1 and the second channel area CH2 are offset from each other in the first horizontal direction HD1.

From a plan view, the common active area CA1a is disposed between the first gate electrode GE1 and the second gate electrode GE2. The common active area CA1a is connected between the first channel area CH1 and the second channel area CH2. The common active area CA1a includes a first section FS1 that is connected to the first channel area CH1, a second section SS1 that is connected to the second channel area CH2, and a third section TS1a between the first section FS1 and the second section SS1.

The first section FS1 of the common active area CA1a extends from the first channel area CH1 in the second horizontal direction HD2. The dimension of the first section FS1 of the common active area CA1a in the first horizontal direction HD1 may be the same as the dimension of the first channel area CH1 in the first horizontal direction HD1. The dimension of the first section FS1 of the common active area CA1a in the first horizontal direction HD1 and the dimension of the first channel area CH1 in the first horizontal direction HD1 may both be the same dimension W1.

The second section SS1 of the common active area CA1a extends from the second channel area CH2 in the second horizontal direction HD2. The dimension of the second section SS1 of the common active area CA1a in the first horizontal direction HD1 may be the same as the dimension of the second channel area CH2 in the first horizontal direction HD1. The dimension of the second section SS1 of the common active area CA1a in the first horizontal direction HD1 and the dimension of the second channel area CH2 in the first horizontal direction HD1 may both be the same dimension W2.

The third section TS1a of the common active area CA1a extends in an oblique direction that intersects the first horizontal direction HD1 and the second horizontal direction HD2. The third section TS1a of the common active area CA1a may have step-shaped boundaries BD1a and BD2a. The third section TS1a of the common active area CA1a may include a plurality of rectangular segments SG1, SG2 and SG3, and may be configured by the rectangular segments SG1, SG2 and SG3 are disposed in a stepwise manner to be offset from each other in the first horizontal direction HD1. The dimension of each of the rectangular segments SG1, SG2 and SG3 in the first horizontal direction HD1 is smaller than the dimension W1 of the first section FS1 of the common active area CA1a in the first horizontal direction HD1 and smaller than the dimension W2 of the second section SS1 of the common active area CA1a in the first horizontal direction HD1. The dimension of each of the rectangular segments SG1, SG2 and SG3 in the first horizontal direction HD1 is W3, and W3 is smaller than W1 and W2.

Because the dimension W3 of the third section TS1a of the common active area CA1a in the first horizontal direction HD1 is smaller than the dimension W1 of the first section FS1 of the common active area CA1a in the first horizontal direction HD1 and smaller than the dimension W2 of the second section SS1 of the common active area CA1a in the first horizontal direction HD1, a larger interval with respect to an adjacent active area may be secured for the sections in TS1a. For example, in the first horizontal direction, the interval between adjacent rectangular segments SG3 of TS1a is larger than the interval between adjacent second sections SS1.

The first separate active area SA1 extends in the second horizontal direction HD2 from one end of the common active area CA1a. The second separate active area SA2 extends in the second horizontal direction HD2 from the other end of the common active area CA1a.

The first transistor TR1 is configured in the common active area CA1a and the first separate active area SA1, and the second transistor TR2 is configured in the common active area CA1a and the second separate active area SA2. The first transistor TR1 and the second transistor TR2 share the common active area CA1a.

Referring to FIG. 5, the first separate active area SA1 includes a first section that is disposed on a side of the first gate electrode GE1 opposite to the common active area CA1a. The second separate active area SA2 includes a second section that is disposed on a side of the second gate electrode GE2 opposite to the common active area CA1a.

A first impurity may be doped into the first section of the first separate active area SA1 to form a first junction area Jn1. The first impurity may be an n-type impurity. The n-type impurity may include phosphorus (P), arsenic (As) and antimony (Sb). The first impurity may be doped into the second section of the second separate active area SA2 to form a second junction area Jn2. The first impurity may be doped into the common active area CA1a to form a third junction area Jn3.

A first gate insulating layer GI1 is disposed between the first gate electrode GE1 and the substrate SUB, and a second gate insulating layer GI2 is disposed between the second gate electrode GE2 and the substrate SUB.

The first gate electrode GE1, the first gate insulating layer GI1, the first and third junction areas Jn1 and Jn3 and the first channel area CH1 constitute the first transistor TR1. The second gate electrode GE2, the second gate insulating layer GI2, the second and third junction areas Jn2 and Jn3 and the second channel area CH2 constitute the second transistor TR2. The first transistor TR1 and the second transistor TR2 share the third junction area Jn3.

A first contact CNT1 may be connected to the first junction area Jn1, a second contact CNT2 may be connected to the second junction area Jn2, and a third contact CNT3 may be connected to the third junction area Jn3.

Referring to FIG. 3, the third contact CNT3 is disposed on the first section FS1 or the second section SS1 of the common active area CA1a. The third contact CNT3 is not disposed on the third section TS1a of the common active area CA1a. Because the third contact CNT3 is disposed on the first section FS1 or the second section SS1 of the common active area CA1a, which has a larger dimension in the first horizontal direction HD1 than any of the rectangular segments of the third section TS1a of the common active area CA1a, the process margin in forming a contact may be improved compared to a case where the third contact CNT3 is formed on a rectangular segment of the third section TS1a of the common active area CA1a.

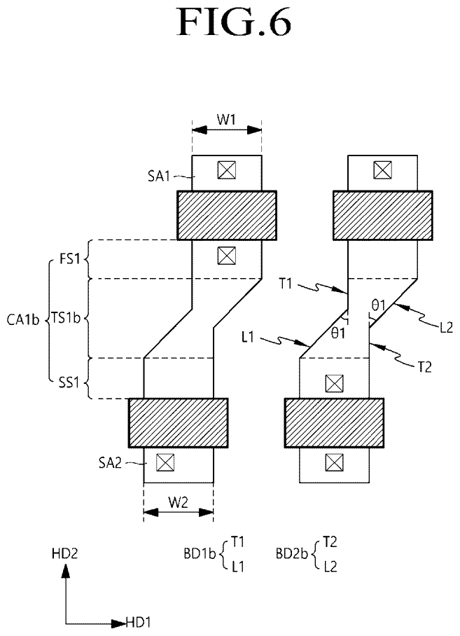

FIG. 6 is a plan view illustrating transistors of a semiconductor device according to an embodiment of the present disclosure.

Referring to FIG. 6, a third section TS1b of a common active area CA1b includes a first boundary BD1b and a second boundary BD2b that face each other in the first horizontal direction HD1.

The first boundary BD1b includes a first straight portion T1 that extends in the second horizontal direction HD2 from a first section FS1 of the common active area CA1b and a first inclined portion L1 that is connected between the first straight portion T1 and a second section SS1 of the common active area CA1b. The first inclined portion extends in an oblique direction intersecting the first horizontal direction HD1 and the second horizontal direction HD2.

The second boundary BD2b includes a second inclined portion L2 that extends in the oblique direction from the first section FS1 of the common active area CA1b and a second straight portion T2 that extends in the second horizontal direction HD2 to connect the second inclined portion L2 and the second section SS1 of the common active area CA1b.

The first inclined portion L1 and the second inclined portion L2 may be parallel to each other. The first inclined portion L1 may have a slope of a first angle θ1 with respect to the first straight portion T1. The second inclined portion L2 may have a slope of the first angle θ1 with respect to the second straight portion T2.

A dimension, in the first horizontal direction HD1, at one end of the third section TS1b of the common active area CA1b that contacts the first section FS1 of the common active area CA1b may be the same as a dimension of the first section FS1 of the common active area CA1b in the first horizontal direction HD1. The dimension of the first section FS1 of the common active area CA1b in the first horizontal direction HD1 may have a size of W1, so the dimension of the one end of the third section TS1b of the common active area CA1b in the first horizontal direction HD1 may also have a size of W1.

A dimension in the first horizontal direction HD1, at the other end of the third section TS1b of the common active area CA1b that contacts the second section SS1 of the common active area CA1b, may be the same as a dimension of the second section SS1 of the common active area CA1b in the first horizontal direction HD1. The dimension of the second section SS1 of the common active area CA1b in the first horizontal direction HD1 may have a size of W2, so the dimension at the other end of the third section TS1b of the common active area CA1b in the first horizontal direction HD1 may also have a size of W2. The dimension, in the first horizontal direction HD1, of the third section TS1b of the common active area CA1b between the first section FS1 and the second section SS1 is smaller than W1 or W2.

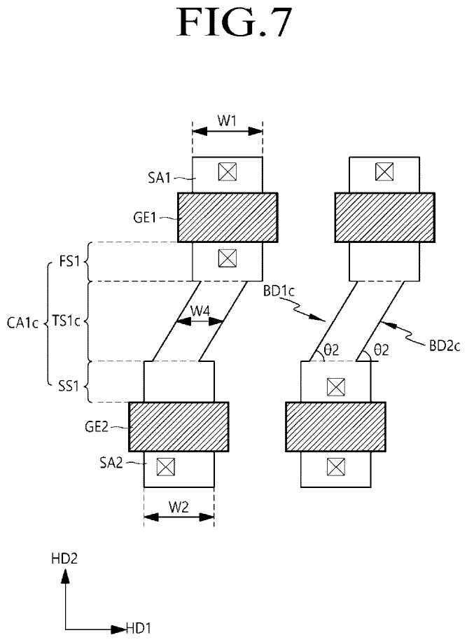

FIG. 7 is a plan view illustrating transistors of a semiconductor device according to an embodiment of the present disclosure.

Referring to FIG. 7, a third section TS1c of a common active area CA1c includes a first boundary BD1c and a second boundary BD2c that face each other in the first horizontal direction HD1.

Each of the first boundary BD1c and the second boundary BD2c may have a straight line shape that extends in an oblique direction intersecting the first horizontal direction HD1 and the second horizontal direction HD2. The first boundary BD1c and the second boundary BD2c may each have a slope of a second angle θ2 that is larger than 0 degrees and smaller than 90 degrees with respect to the second horizontal direction HD2.

When the dimension of a first section FS1 of the common active area CA1c in the first horizontal direction HD1 is W1 and the dimension of a second section SS1 of the common active area CA1c in the first horizontal direction HD1 is W2, the dimension of the third section TS1c of the common active area CA1c in the first horizontal direction HD1 has a size of W4, which is smaller than W1 and W2.

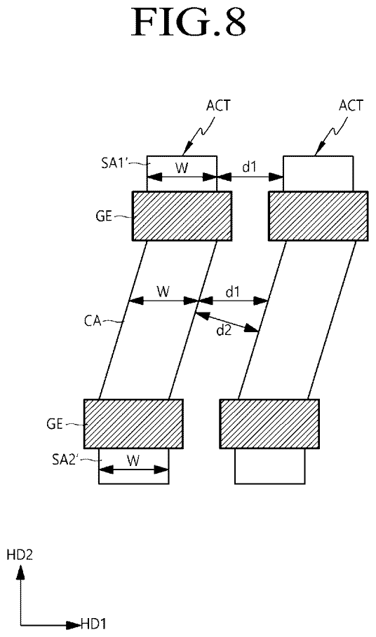

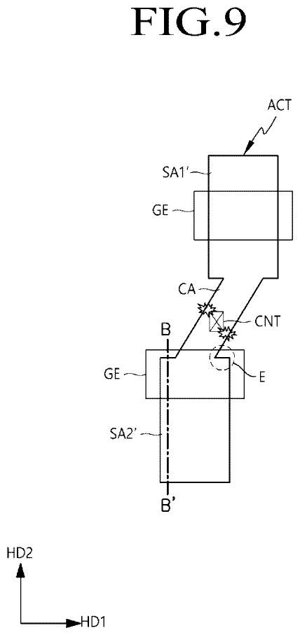

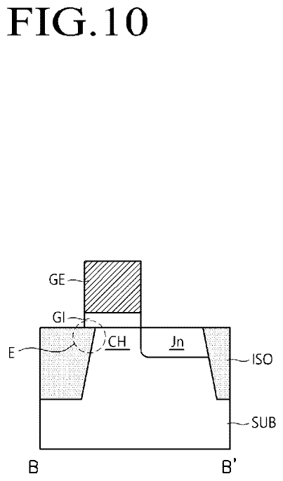

FIG. 8 and FIG. 9 are plan views illustrating transistors for comparison with the present disclosure, and FIG. 10 is a cross-sectional view taken along a line B-B′ of FIG. 9.

Referring to FIG. 8, unlike the present disclosure, the dimension of a common active area CA in the first horizontal direction HD1 may be configured to have the same size as the dimension of each of first and second separate active areas SA1′ and SA2′ in the first horizontal direction HD1.

In this case, the interval between the first separate active areas SA1′ of neighboring active areas ACT has a size of d1, the interval between the common active areas CA of the neighboring active areas ACT has a size of d2, and d2 is smaller than d1. For example, when the boundary of the common active area CA has a slope of θ with respect to the second horizontal direction HD2, d2 has a value of d1X.

An isolation layer that defines the active areas ACT may be formed by forming a trench in a substrate and gap-filling the trench with an insulating material. When the interval between neighboring common active areas CA is narrow, the probability of a defect occurring due to an insufficient process margin in a process of gap-filling the insulating material increases. In addition, due to an insufficient thickness of the isolation layer between neighboring common active areas CA, interference may occur between neighboring transistors, which may cause functional errors in the transistors.

Referring to FIG. 9 and FIG. 10, when the dimension of the common active area CA in the first horizontal direction HD1 is determined to be smaller than the dimension of the first and second separate active areas SA1′ and SA2′ in the first horizontal direction HD1, a gap-fill defect during forming an isolation layer ISO and interference between neighboring transistors may decrease.

However, due to decrease in the dimension of the common active area CA, a process margin becomes insufficient during a process of forming a contact CNT connected to the common active area CA, and due to the insufficient process margin, a defect may occur in which the contact CNT comes into contact with the isolation layer ISO around the common active area CA. In addition, when misalignment occurs between the common active area CA and a gate electrode GE, as illustrated in an area E, the isolation layer ISO may be placed under the gate electrode GE, which may cause gate induced drain leakage (GIDL).

According to embodiments of the present disclosure, a common active area is divided into a third section that extends in an oblique direction and a first section and a second section on both sides of the third section, and the dimension of the third section in a first horizontal direction is determined to have a size smaller than the dimension of the first section in the first horizontal direction and the dimension of the second section in the first horizontal direction. Therefore, the margin of a gap-fill process for forming an isolation layer may be increased to suppress a process defect, and the sufficient thickness of the isolation layer may be secured to suppress interference between neighboring transistors. Also, by preventing the isolation layer from being placed under a gate electrode, it is possible to suppress GIDL. Moreover, by connecting a contact to be connected to the common active area to the first section or the second section of the common active area, the margin of a contact process may be improved.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor device comprising:
a first transistor; and
a second transistor sharing an active area with the first transistor,
wherein the active area includes a common active area between a channel area of the first transistor and a channel area of the second transistor,
wherein the common active area from a plan view comprises:
a first section extending in a second horizontal direction perpendicular to a first horizontal direction from the channel area of the first transistor;
a second section extending in the second horizontal direction from the channel area of the second transistor; and
a third section connected between the first section and the second section, and extending in an oblique direction intersecting the first horizontal direction and the second horizontal direction, and
wherein at least a portion of the third section has a dimension in the first horizontal direction that is different from the dimension of each of the first section and the second section in the first horizontal direction.

2. The semiconductor device according to claim 1, wherein at least a portion of the third section has the dimension in the first horizontal direction that is smaller than the dimension of each of the first section and the second section in the first horizontal direction.

3. The semiconductor device according to claim 1, further comprising
a contact connected to one of the first and second sections of the common active area.

4. The semiconductor device according to claim 1, wherein the third section is configured in a step shape.

5. The semiconductor device according to claim 1, wherein the third section is configured as a plurality of rectangular segments are disposed in a stepwise manner.

6. The semiconductor device according to claim 5, wherein each of the plurality of rectangular segments has the dimension in the first horizontal direction that is smaller than the dimension of each of the first section and the second section in the first horizontal direction.

7. The semiconductor device according to claim 1, wherein
the third section includes a first boundary and a second boundary that face each other in the first horizontal direction,
the first boundary includes a first straight portion that extends in the second horizontal direction from the first section and a first inclined portion that is connected between the first straight portion and the second section and extends in the oblique direction, and
the second boundary includes a second inclined portion that extends in the oblique direction from the first section and a second straight portion that is connected between the second inclined portion and the second section and extends in the second horizontal direction.

8. The semiconductor device according to claim 7, wherein the first inclined portion and the second inclined portion are parallel to each other.

9. The semiconductor device according to claim 1, wherein each of boundaries of the third section has a straight line shape that extends in the oblique direction.

10. The semiconductor device according to claim 1, wherein the first section of the common active area has the dimension in the first horizontal direction that is the same as the dimension of the channel area of the first transistor in the first horizontal direction.

11. The semiconductor device according to claim 1, wherein the second section of the common active area has the dimension in the first horizontal direction that is the same as the dimension of the channel area of the second transistor in the first horizontal direction.

12. A semiconductor device comprising:
a substrate defined with an active area; and
first and second gate electrodes extending in a first horizontal direction on the substrate, and disposed parallel to each other;
wherein the active area comprises:
a common active area disposed between the first gate electrode and the second gate electrode when viewed on a plan view;
a first separate active area extending in a second horizontal direction perpendicular to the first horizontal direction from the common active area, and intersecting the first gate electrode; and
a second separate active area extending in the second horizontal direction from the common active area, and intersecting the second gate electrode,
wherein the common active area comprises:
a first section extending in the second horizontal direction from the first separate active area;
a second section extending in the second horizontal direction from the second separate active area; and
a third section connected between the first section and the second section, and extending in an oblique direction intersecting the first horizontal direction and the second horizontal direction, and
wherein at least a portion of the third section has a dimension in the first horizontal direction that is different from the dimension of each of the first section and the second section in the first horizontal direction.

13. The semiconductor device according to claim 12, wherein at least a portion of the third section has the dimension in the first horizontal direction that is smaller than the dimension of each of the first section and the second section in the first horizontal direction.

14. The semiconductor device according to claim 12, further comprising
a contact connected to one of the first and second sections.

15. The semiconductor device according to claim 12, wherein each of boundaries of the third section is configured in a step shape.

16. The semiconductor device according to claim 12, wherein
the third section includes a first boundary and a second boundary that face each other in the first horizontal direction,
the first boundary includes a first straight portion that extends in the second horizontal direction from the first section and a first inclined portion that is connected between the first straight portion and the second section and extends in an oblique direction, and
the second boundary includes a second inclined portion that extends in the oblique direction from the first section and a second straight portion that is connected between the second inclined portion and the second section and extends in the second horizontal direction.

17. The semiconductor device according to claim 12, wherein each of boundaries of the third section is configured in a straight line shape that extends in the oblique direction.

18. The semiconductor device according to claim 12, wherein the first section of the common active area has the dimension in the first horizontal direction that is the same as the dimension of the first separate active area in the first horizontal direction.

19. The semiconductor device according to claim 12, wherein the second section of the common active area has the dimension in the first horizontal direction that is the same as the dimension of the second separate active area in the first horizontal direction.

20. A semiconductor device comprising:
a memory cell array; and
a page buffer circuit connected to the memory cell array through bit lines,
wherein the page buffer circuit includes first and second transistors that share one active area,
wherein the active area includes a common active area between a channel area of the first transistor and a channel area of the second transistor,
wherein the common active area from a plan view comprises:
a first section extending in a second horizontal direction perpendicular to a first horizontal direction from the channel area of the first transistor;
a second section extending in the second horizontal direction from the channel area of the second transistor; and
a third section connected between the first section and the second section, and extending in an oblique direction intersecting the first horizontal direction and the second horizontal direction, and
wherein at least a portion of the third section has a dimension in the first horizontal direction that is smaller than the dimension of each of the first section and the second section in the first horizontal direction.
